(19) United States
(12) Patent Application Publication
(10) Pub. No.: US 2017/0054510 A1
(43) Pub. Date: Feb. 23, 2017

(54) ELECTRO-OPTICAL FINITE IMPULSE RESPONSE TRANSMIT FILTER

(71) Applicant: MULTIPHY LTD., Ness-Ziona (IL)

(72) Inventors: Anthony Eugene ZORTEA, Pipersville, PA (US); Dan SADOT, Kfar Bilu (IL); Russell ROMANO, Allentown, PA (US)

(73) Assignee: MULTIPHY LTD., Ness-Ziona (IL)

(21) Appl. No.: 15/238,608

(22) Filed: Aug. 16, 2016

Related U.S. Application Data
(60) Provisional application No. 62/205,923, filed on Aug. 17, 2015.

(51) Int. Cl. H04B 10/516; H03H 21/00

(52) U.S. Cl. CPC H04B 10/516; H03H 21/0012; H03H 2021/0085

(57) ABSTRACT

An electro-optical FIR transmit filter comprising a segmented MZM including a plurality of MZM segments, for receiving an input optical traveling wave to be filtered; an electrical field driver, for applying a controlled electrical field required for modulation of each MZM using a control signal which controls the electrical field; delay cells associated with at least one MZM, for aligning the control signal with a travelling optical wave; and at least one electrical xT delay cell representing a filter delay, for electrically adjusting the timing of the control signal. The FIR filter's coefficients are implemented in the optical domain by determining the amount of MZM segments driven by each xT delay cell, with respect to the total number of MZM segments.

### CROSS-REFERENCE TO RELATED APPLICATION

This application claims the benefit of U.S. Provisional Application No. 62/205,923, filed Aug. 17, 2015, the disclosure of which is incorporated herein by reference in its entirety.

### FIELD OF THE INVENTION

The present invention relates to the field of optical communication. More particularly, the invention relates to a power efficient pre-equalizer capable of equalizing complex transfer functions, for optical impairment compensation.

### BACKGROUND OF THE INVENTION

High speed fiber optic links require high bandwidth transmit signals. A fiber optical link typically includes an electrical transmitter driving an electrical-to-optical transducer, such as a Mach-Zehnder Modulator (MZM).

A MZM is a component which can modify the amplitude of an optical wave which enters one side of the MZM and is then split to two arms (and to two beams), one of which includes a phase modulator. At the other side of the MZM the two beams are recombined and, according to the modulating phase, are interfered either constructively or destructively. The phase modulator can be implemented by voltage that is applied to the MZM arm, which changes the refractive features of the arm's material.

Preserving, or even improving, the signal bandwidth from the electrical signal to the final optical signal is desirable, but can be expensive (in terms of power and size) for very high speed links. This problem is especially difficult in silicon photonics applications employing Mach-Zehnder modulators of relatively long length because the electrical signal must be distributed over a great distance. This distribution will introduce loss at high frequencies.

An optical communication channel normally introduces optical impairments and distortions and therefore, should be equalized. Equalization may be performed by a pre-equalizer, which is capable of equalizing complex transfer functions, in order to compensate these optical impairments and distortions. A widely used implementation of equalization (such as a pre-equalizer, which performs equalization at the transmitting side) is by using a Finite Impulse Response (FIR) filter.

A FIR filter can be defined as a weighted sum of a variously delayed input signal. In order to implement a FIR filter, a method for delaying a signal in the optical domain is required. Applying a delay to a signal in the optical domain is expensive due to the speed in which the signal propagates, i.e. the speed of light, which requires long physical lengths in order to provide a delay.

FIG. 1. (prior art) illustrates a block diagram representing the operation of a n-order FIR filter. An input signal 101 is split to a chain of n delay cells 102-105. Each of the delay cells applies a delay on the input signal, therefore representing a delayed sample of the input signal. The outputs of the delay cells are inserted to amplitude gain cells 106-109, which modify the amplitude of each sample according to the filter's transfer function. The outputs of the amplitude gain cells are inserted into an accumulator 110 which sums the resulting components, and assembles the filter's output signal 111.

Utilizing this method of delays for an FIR filter would be wasteful and expensive, because of the different delay orders required for the MZM segmentation and the filter sampling delays, which would result in physically large systems.

It is therefore an object of the present invention to provide a method and system for implementing a small scale time domain based digital FIR filter, which is power efficient.

It is another object of the present invention to provide a method and system for implementing a small scale time domain based digital FIR filter, without the need to use a coherent optical system.

Other objects and advantages of this invention will become apparent as the description proceeds.

### SUMMARY OF THE INVENTION

The present invention is directed to an electro-optical FIR transmit filter comprising a segmented MZM including a plurality of MZM segments, for receiving an input optical traveling wave to be filtered; an electrical field driver connected to each MZM segment, for applying a controlled electrical field required for modulation of each MZM using a control signal; a control signal input, for inputting the control signal to control the electrical field, required for optical wave modulation; at least one delay cell associated with at least one MZM, for aligning the control signal with a travelling optical wave; and at least one electrical xT delay cell representing a filter delay, for electrically adjusting the timing of the control signal. The FIR filter's coefficients are implemented in the optical domain by determining the amount of MZM segments driven by each xT delay cell, with respect to the total number of MZM segments.

All the electrical field drivers may apply an electrical field of a constant magnitude to MZM segments.

The FIR filter's sampling rate may be implemented in the electrical domain by determining the delay time-duration of the xT delay cells according to the FIR filter's sampling rate.

Each MZM segment except for the first MZM segment may have a delay cell associated with it.

The sign of a coefficient may be implemented in the electrical domain by controlling the polarity of P and N signals of the electrical field driver, when working with differential electronic signals.

### BRIEF DESCRIPTION OF THE DRAWINGS

FIG. 1 (prior art) illustrates a block diagram of a FIR filter;

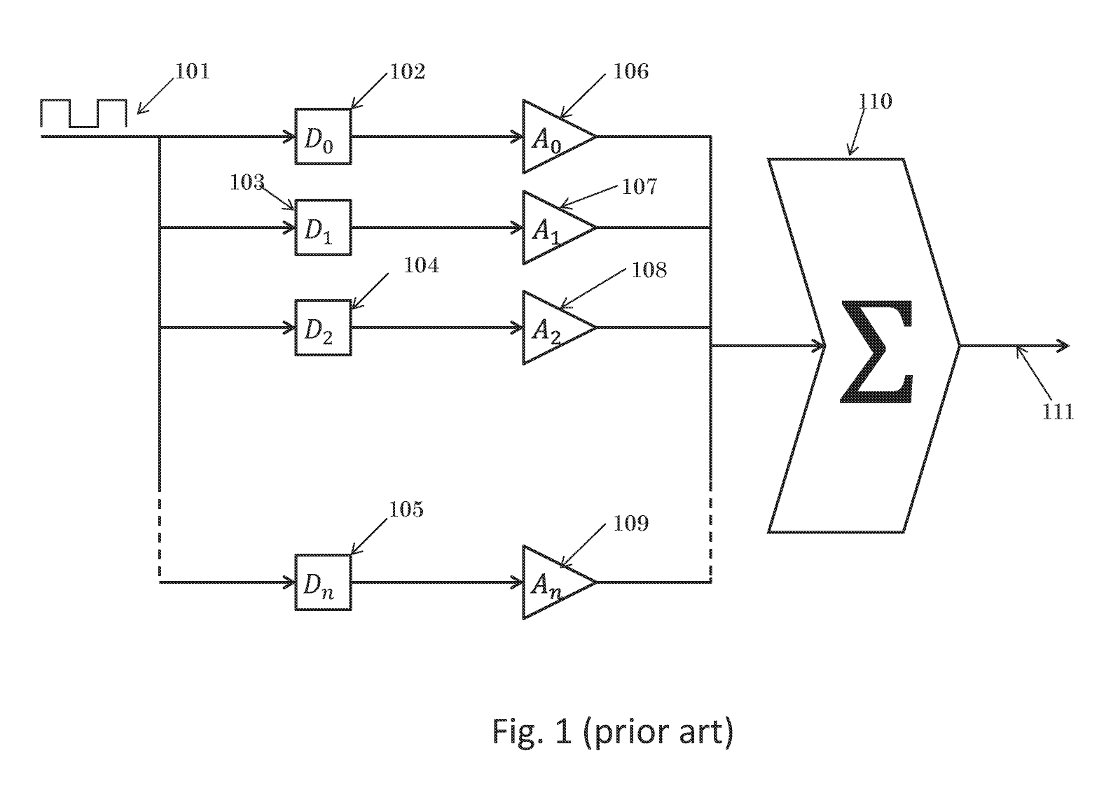

FIG. 2 (prior art) illustrates a segmented MZM driven by individual electric field drivers;

FIG. 3 illustrates the implementation of an electro-optical FIR filter according to an embodiment of the present invention; and

FIG. 4 illustrates an exemplary optical wave with several sampling points.

### DETAILED DESCRIPTION OF THE INVENTION

The present invention introduces a novel electro-optical FIR filter implemented in the electro-optical domain.

The use MZMs introduces a limitation, when attempting to modulate waves in different waveguides. It has been proposed by Kato T. et al. in “InP modulators with linear accelerator like segmented electrode structure” (Optical Fiber Communications Conference and Exhibition, 2014) to segment the MZM and drive the segments with individual electrical transmitters.

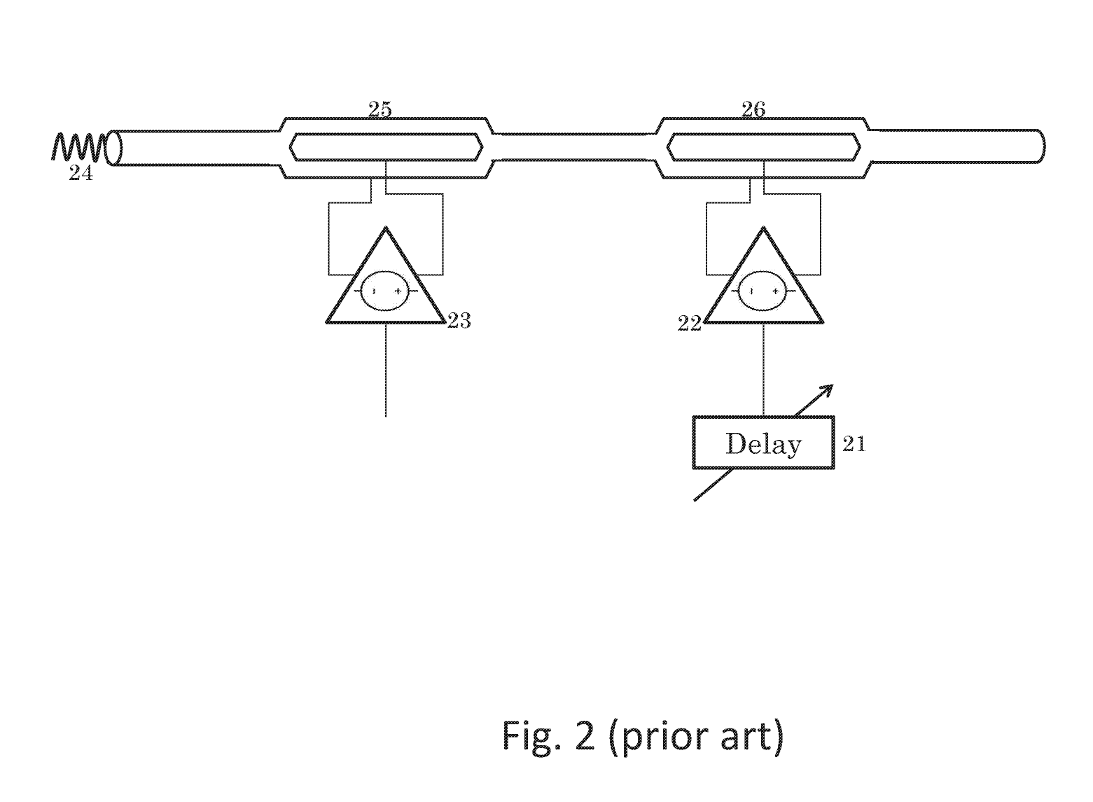

FIG. 2 (prior art) illustrates a block diagram of a system according to the implementation proposed by Kato et al. Delay 21 in this architecture is provided to align the signals of the electrical field driver 22-23 with the optical travelling wave 24. The sizes of these delays are of smaller order than the Baud rate at which data is transferred over the optical fiber. The electrical fields are applied to the bottom arms of the MZMs 25-26 in order to perform phase modulation. This solution allows use of physically small MZMs in a variety of waveguides. In this case, however, it would be expensive to maintain wideband transmitter signals due to the high speed and the distribution over large areas.

Delaying a signal in the optical domain is expensive due to the speed of light which requires vast lengths to provide a delay. On the other hand, delaying in the electrical domain is inexpensive, where a single gate delay may provide a single cycle delay for a 60 GBaud system.

Summation in the electrical domain is expensive due to the large circuitry required, and the parasitics caused by it. On the other hand, summation in the optical domain is essentially free, inasmuch each segment of a segmented MZM can add the optical signals to the total sum.

Weighting can be achieved by choosing the amount of segments which are driven by the delayed electrical transmitters with respect to the total number of segments.

Generating negative coefficients, as required in many FIRs, can be handled in the differential structure by reversing electronic P and N signals, when working with differential electronic signals.

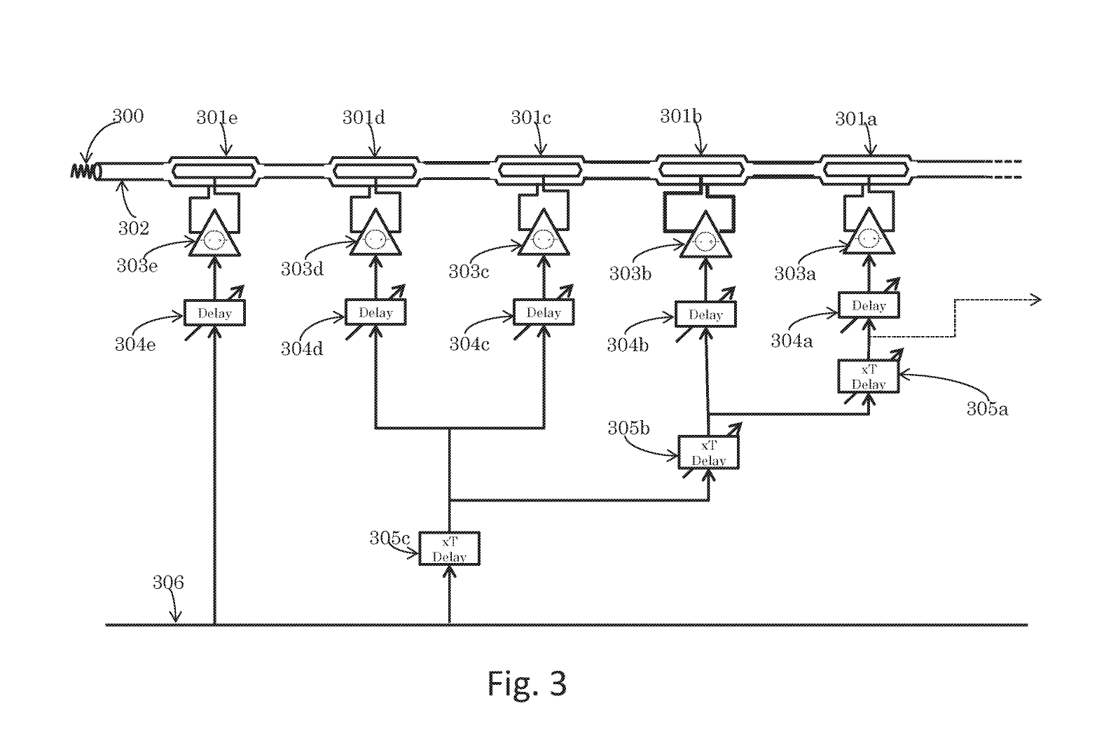

FIG. 3 schematically illustrates a block diagram of part of a FIR filter according to an embodiment of the invention. The filter design implemented by the block diagram of FIG. 3 can be a third order FIR filter, having four various distributions to the main transmission signal. Otherwise the filter design of FIG. 3 can be part of a FIR filter of order higher than three. Control line 306 activates the circuit by providing timing signals for the identical electric field drivers 303a-303e. Because the modulation is segmented, and according to Kato et al., delay cells 304a-304e introduce adjustable delays to each electronic modulation cell in order to align the modulation action with the travelling wave within the MZMs 301a-301e. In addition to delay cells 304a-304f, additional adjustable xT delay cells 305c-305e are introduced to apply the required delay for the filter operation. The size of the xT delays is constant and, in terms of time, is in the order of the Baud period T of the data transferred through the optical channel. The exact size of each xT is determined according to the filter design's sampling rate. The filter coefficients are implemented by choosing the amount of segments which are driven by each xT delayed electrical transmitter, with respect to the total number of segments. E.g., delay cell 305c drives two segments 304d-c, and therefore has more weight (40%) than the other delay stages (20% each).

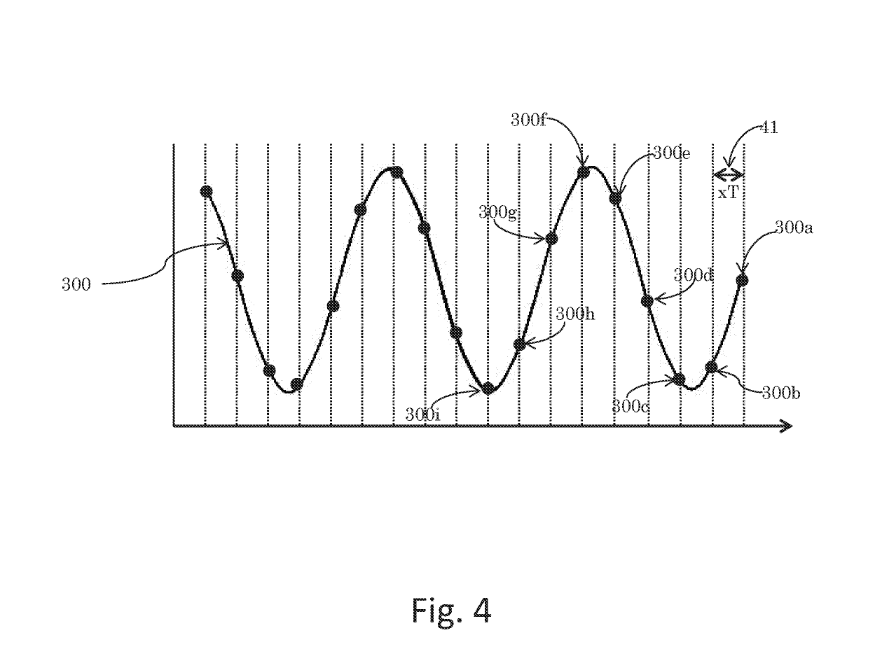

FIG. 4 illustrates an exemplary optical wave 300, with several sampling points 300a-300i. The time difference 41 between each sample point is xT, implying the sampling rate of the filter design.

The filtering process will now be described with reference to FIG. 3 and FIG. 4. Optical signal 300 enters the filter segment of an optical fiber 302. At the first stage, the influence on the first 5 sample points of the wave 300, i.e. 300a-300e is discussed.

As the signal propagates throughout the filter, it passes through a plurality of MZMs 301a-301e. Each MZM applies an amount of modulation to a part of the signal. The first segment of the filter consists of a delay cell 304e, an electric field driver 303e and an MZM 301e. The electric field driver 303e applies an electric field to the bottom arm of the MZM 301e therefore affecting cycle 300e of the signal 300. At the same time, the second segment of the filter, consisting delay cell 304d, electric field driver 303d, MZM 301d and xT delay cell 305c, affects cycle 300d of the signal 300, according to the second coefficient of the filter. At the same time the third segment, consisting delay cell 304c, electric field driver 303c, MZM 301c and xT delay cell 305c, affects cycle 300c of the signal 300, according to the third coefficient of the filter. Similarly, at the same time the fourth and fifth segments, consisting 301d-305d and 301e-305e respectively, affect the fourth and fifth cycles 300e and 300f of the signal according to the fourth and fifth filter coefficients respectively. The result of this stage is five sample points (300a-300e) that underwent various levels of filtering, all added to a single wave.

It may be noticed that xT delay cell 305c drives two MZMs. This represents a larger weight of the second coefficient in respect to the other coefficients.

It may also be noticed that one of the electric field drivers, i.e. 303b, is connected in an inverted manner (i.e., the negative pole is connected to the top arm of the MZM and the positive pole to the bottom). This is an example of how a negative coefficient is achieved according to an embodiment of the invention.

Next, a second filtering stage occurs, and each sample point 300b-300e propagates to the following segment in the filter, while the first sample point 300a leaves the filter and the next sample point 300f enters the first segment. The influence of the filter on the various sample points is similar to the description above of the influence of the filter on the first five cycles, only that in this period cycle 300b is influenced by components 301a, 303a and 304a, and cycles 300c-300f are influenced by components 301b-301e, 303b-303e, 304b-304e and 305b-305c respectively and according to FIG. 3.

As time passes, the sample points propagate throughout the filter and the signal 300 is filtered according to the designed filter.

As various embodiments have been described and illustrated, it should be understood that variations will be apparent to one skilled in the art without departing from the principles herein. Accordingly, the invention is not to be limited to the specific embodiments described and illustrated in the drawings.

1. An electro-optical FIR transmit filter comprising:
a. a segmented MZM including a plurality of MZM segments, for receiving an input optical traveling wave to be filtered;
b. an electrical field driver connected to each MZM segment, for applying a controlled electrical field required for modulation of each MZM using a control signal;
c. a control signal input, for inputting said control signal to control the electrical field, required for optical wave modulation;
d. at least one delay cell associated with at least one MZM, for aligning said control signal with a travelling optical wave; and
e. at least one electrical xT delay cell representing a filter delay, for electrically adjusting the timing of said control signal,
wherein the FIR filter's coefficients are implemented in the optical domain by determining the amount of MZM segments driven by each xT delay cell, with respect to the total number of MZM segments.

2. The electro-optical FIR transmit filter of claim 1, wherein all the electrical field drivers apply an electrical field of a constant magnitude to MZM segments.

3. The electro-optical FIR transmit filter of claim 1, wherein the FIR filter's sampling rate is implemented in the electrical domain by determining the delay time-duration of the xT delay cells according to the FIR filter's sampling rate.

4. The electro-optical FIR transmit filter of claim 1, wherein each MZM segment except for the first MZM segment has a delay cell associated with it.

5. The electro-optical FIR transmit filter of claim 1, wherein the sign of a coefficient is implemented in the electrical domain by controlling the polarity of P and N signals of the electrical field driver, when working with differential electronic signals.
